(19) United States
(12) Patent Application Publication
(10) Pub. No.: US 2005/0215054 A1
(43) Pub. Date: Sep. 29, 2005

(54) Feed-through process and amplifier with feed-through

(76) Inventors: Frank Engel Rasmussen, Hellerup (DK); Jorgen Skindhoj, Hellerup (DK); Anders Erik Petersen, Hellerup (DK)

Correspondence Address: DYKEMA GOSSETT PLLC, FRANKLIN SQUARE, THIRD FLOOR WEST, 1300 I STREET, NW, WASHINGTON, DC, 20005, US

(21) Appl. No.: 10/516,886

(22) PCT Filed: May 22, 2003
(86) PCT No.: PCT/DK03/00339

§ 371 Date: Jun. 14, 2005

(30) Foreign Application Priority Data
Jun. 7, 2002 (DK) PA 2002 00874

(51) Int. Cl. H01L 21/308; H01L 29/40

(52) U.S. Cl. 438/667; 257/621; 438/753

(57) ABSTRACT

The invention concerns a process for generating a feed-through in a semiconductor wafer, which has electric circuitry embedded in a front surface whereby the hole for the feed-through is generated by the combined use of a front side protection layer and a wet KOH etch process etching the hole from the back side of the wafer, where a photomasking process is subsequently used do define the via followed by deposition of the via material.

### AREA OF THE INVENTION

The invention concerns a process for generating a feed-through in a semiconductor wafer, which has electric circuitry embedded in a first surface. The embedded circuitry could be a CMOS or similar electronic device. The invention further concerns an amplifier comprising electric circuitry embedded in a first side of a semiconductor wafer and a feed-through from the first to a second side of the semiconductor wafer.

### BACKGROUND OF THE INVENTION

Amplifiers are produced on wafers and singulated after production. It has been proposed to mount separate electronic components directly on the wafer prior to singulation of the individual amplifiers. This technique is space saving as it becomes possible to omit the printed circuit board, as all components for driving the amplifier can be placed on the surface of the integrated circuit embedded in the silicon wafer. In some cases it is a problem to provide sufficient space also for the bondpads for in/out signals and for power supply for the IC on the surface when also the electric components are placed here. In this case it would be advantageous to be able to either place the bondpads or the electric components on the opposite side of the silicon wafer with the embedded IC. This requires electric leads or vias connecting the two sides of the semiconductor wafer. In the following such an electric conducting path leading through the wafer material from one to the other side thereof is called a feed-through or a via. The via or feed-through comprises a hole all the way through the wafer material, an insulation layer covering the inside surface of the hole and electrically conducting material preferably metal. In this way an electrically leading path from the one to the other side of the wafer is created which is electrically isolated from the other parts of the wafer.

Such vias have peen proposed previously, but in the present case the semiconductor wafer has active IC circuitry embedded in one of the surfaces thereof, and this surface must be protected against detrimental influence of: high temperature, chemical etching and mechanical damage. It has been proposed to mount the wafer in an enclosure or mechanical fixture, which leaves one face of the wafer free to be contacted by the etch fluid. This has proved to be cumbersome, and there is a great risk of shattering the wafer due to mechanical stressing of the fragile wafer caused by the bulky mechanical fixture or due to pressure differences between front and back side of the wafer occurring during processing. In addition the use of a mechanical fixture hampers the possibility of obtaining a batch process.

### SUMMARY OF THE INVENTION

The invention proposes a process, which solves the above problems.

This is done in a process where the hole for the feed-through is generated by the combined use of a front side protection layer and a wet KOH etch process etching the hole from the back side of the wafer, where a photomasking process is subsequently used do define the vias followed by deposition of the via material.

The frontside protection layer protects the sensitive CMOS surface from being attacked by the KOH etch chemicals when the wafer is submerged in the etch bath. In this way the mounting of the sensitive wafer in an enclosure is avoided. Having formed the holes for the vias in the wafer, the via leads are defined using a photomasking technique and subsequently the via material is deposited. The combined use of these simple techniques ensures that feed-throughs can be made in a very industrial way, and can be fabricated in a semiconductor wafer containing sensitive CMOS circuitry without detrimental influence on the functionality of such circuitry. The combination of techniques described in the present invention offers a simple and inexpensive process for fabrication of electrical feedthroughs that is highly applicable for industrial production. The advantages are especially accomplished by eliminating the need for a bulky mechanical fixture during etching of the wafer through-hole and by providing means for opening the wafer through-hole without damaging the CMOS circuitry.

In an embodiment of the invention the front side protection layer comprises: a) an electrical insulation layer, preferably a PECVD silicon nitride layer; b) a KOH resistant metallic layer, preferably a TiW layer and an Au layer.

During processing of the feed-through the CMOS wafer is repeatedly placed upside down in wafer holders in various process equipment. Thus, a protective layer is placed on the front side of the wafer in order to avoid mechanical damage of the CMOS surface. Especially the aluminum pads are easily scratched in such handling of the wafer.

The protective layer has to be selectively removable relative to the CMOS passivation layer, i.e. the two layers have to be complementary. In this process a PECVD nitride protection layer has been utilised. Preferably a TiW diffusion/adhesion layer and Au protection/seed layer are deposited on the nitride protection layer by means of sputtering. An additional Au layer may be electroplated on top of the sputtered Au layer in order to provide a dense surface film. If the Au layer is to become part of the via on the front side, the nitride protection layer must be removed on the bond pads of the CMOS prior to deposition of the metal layers, and this can be done in a well known reactive ion etching (RIE) dry etch process.

The combined effect of the protection layers, is that the CMOS surface is thoroughly protected against mechanical and chemical which could be caused by the processing of the feed-through-holes.

The formation of through-holes from the back side comprises a number of steps whereby:
a KOH etch resistant layer is deposited on the back side,
openings for the through-holes are defined in the KOH etch resistant layer by a photomasking process in alignment with the circuitry embedded in the front side of the semiconductor wafer,
the openings for the through-holes are etched in the KOH resistant layer, and
the through-holes in the semiconductor wafer are etched using KOH.

Preferably the KOH etch resistant layer is a silicon nitride layer, which is deposited by a PECVD process, and the openings for the through-holes are etched through the silicon nitride layer by a RIE process. Typically the used gas mixtures comprises one or several of the gases CHF₃, SF₆, O₂.

The KOH etch process stops at the front side of the semiconductor wafer when the electrical insulation layer is encountered. This leaves a thin membrane-like structure in the bottom of the through-hole comprising a local part of the front side electrical insulation and a local part of the KOH resistant metallic layer(s).

The membrane-like structure is composed of local parts of the front side electric insulation and KOH etch-resistant metallic layer(s). In an embodiment of the invention the membrane like structure is etched from the back side through the formed holes in the semiconductor wafer. Opening of the through-holes in this way is advantageous, as the semiconductor wafer itself works as the etch mask, and a front side photolithographic process is avoided.

Wet and dry etch processes are available for removal of the local part of the front side electric insulation in the bottom of the through-hole. These processes also strip the KOH resistant etch mask material used to define the through-hole openings on the back side. Preferably a dry etching process such as reactive ion etching is used for removal of the local part of the front side electric insulation, which remains in the bottom of the through-hole.

Likewise both wet and dry etch processes are available for removal of the local part of the KOH resistant metallic layer(s) in the bottom of the through-hole. Preferably a wet etch process is used. During said wet etching process a protective layer of photoresist on the front side of the semiconductor wafer prevents complete etching of the metallic layer(s) on the front side.

In a further embodiment the thin membrane-like structure in the bottom of the through-hole comprising a local part of the front side electrical insulation layer and a local part of the KOH resistant metallic layer(s) is removed from the front side of the semiconductor wafer using a photolithographic process in alignment with the formed through-holes followed by suitable etching processes.

The through-holes have now been formed and a base for the vias must be provided on both back and front side. To this end the following processes are performed on the back side:
the back side of the wafer and the inside of the through-holes is covered by an insulating layer, preferably a silicon oxide layer deposited by means of PECVD,
the silicon oxide layer is covered by a conductive metal layer in order to provide a basis for electrochemical deposition of metal, preferably constituted by a deposited TiW adhesion layer and a deposited Au seed layer.

This provides a surface on the back side and inside the through-holes, which is electrically insulated from the semiconductor wafer and which acts as a suitable base for electrochemical deposition of metal.

On the front side the following is done if necessary:
residual silicon oxide, especially in the areas around the through-holes is removed, preferably by sputter etching.

Said removal of silicon oxide leaves the Au surface free of insulating particles and clean to receive the conductive via material.

The structure of the vias is defined by a photomasking process and the via material is deposited.

Preferably the photomasking process constitutes a photolithographic process where a photoresist is deposited by means of electrodeposition. The electrodepositable photoresist has the ability to uniformly coat highly structured surfaces such as the semiconductor wafer with through-holes. Following deposition the photoresist is exposed through a mask defining the negative image of the feed-through back and front side respectively. After development a mould for deposition of feed-through metal is obtained.

The vias are formed by deposition of via metal. Preferably the vias are formed by electrochemical deposition of Cu or a combination of electrochemical deposition of Cu and Ni.

After feedthrough metal deposition the photoresist is stripped on both sides of the semiconductor wafer and the underlying TiW/Au layer is selectively removed to the feed-through metal on both sides of the semiconductor wafer.

Finally the semiconductor wafer with processed feed-through is passivated in order to protect the individual chips from the ambient environment present during use of the chip. Preferably the passivation is done using BCB (BenzoCycloButene) or the combination of a PECVD processed layer and BCB. The passivation is patterned by UV-illumination of the BCB through a photomask and by dry etching of the underlying PECVD processed layer, if present. The passivation is removed above metallized areas designed for terminals for input/output signals and in metallized areas designed for later processing of solder bumps.

### BRIEF DESCRIPTION OF THE DRAWINGS

FIG. 1 shows in a schematic form the steps 1-14 in the processes leading to the formation of the feed-through,

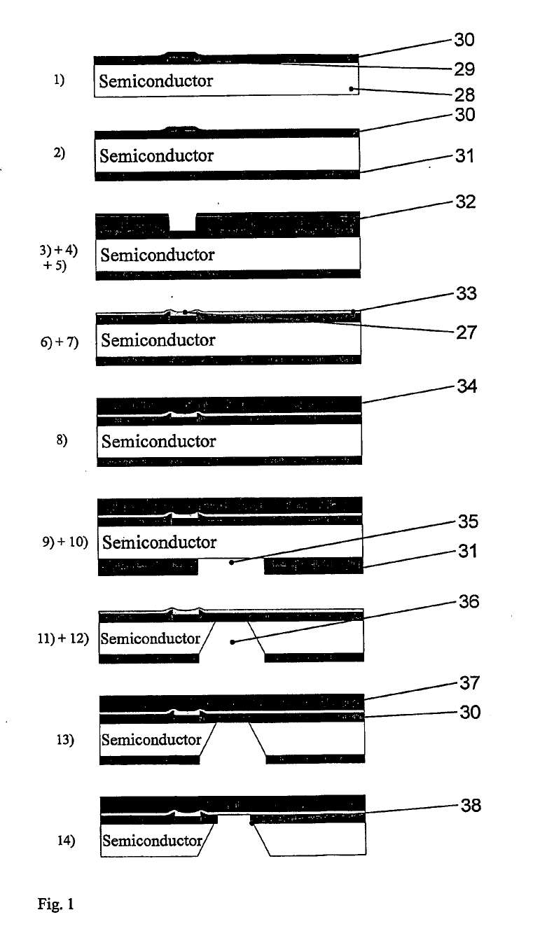

FIG. 2 shows the steps 15-26 in the feed-through processing.

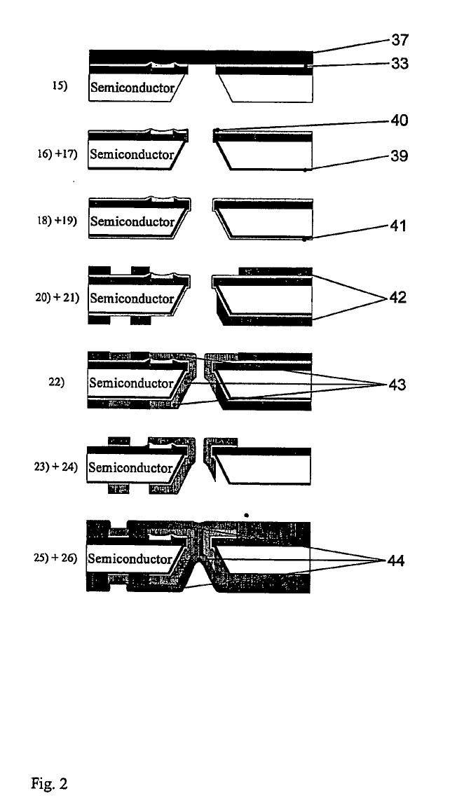

### DESCRIPTION OF A PREFERRED EMBODIMENT

In the preferred embodiment a silicon wafer 28 is used, but more advanced wafers like silicon on insulator may also be used within the scope of the invention.

1) Deposition of PECVD Nitride 30 on Front Side:

During processing of the feed-throughs the CMOS wafer is repeatedly placed upside down in wafer holders in various process equipment. Thus, a protective layer is needed on the front side of the wafer in order to avoid mechanical damage of the CMOS surface. Especially the aluminium pads are easily scratched in such handling of the wafer. Furthermore, the sensitive CMOS circuits have to be protected from the etchants used for e.g. etching of the through-holes.

The protective layer has to be selectively removable with respect to the CMOS passivation layer, i.e. the two layers have to be complementary. In this process a PECVD silicon nitride protection layer 30 has been utilised. In the following process a single electric connections is provided through the formed hole, but several separate electric connections may be provided in one through hole.

2) Deposition of PECVD Nitride 31 on Back Side:

In the through-hole etch process, an etch mask defining the size of the through-holes is needed on the back side of the wafer. The etch mask serves as protection layer in regions not supposed to be etched, i.e. the etch mask material has to be chemically resistant to the etchant used. Silicon nitride is resistant to potassium hydroxide (KOH), which is the chosen etchant in this process. In the present invention a KOH resistant silicon nitride deposited by means of PECVD is used as an etch mask.

3)+4)+5) RIE of Silicon Nitride on Bond Pads:

The silicon nitride above the bond pads 28 on the front side of the wafer is dry etched in order to facilitate electrical connection of the protective coating (deposited in process step 5 and 6) to the aluminium bond pads 28. An etch mask 32 is applied prior to the RIE process. This mask is removed after the RIE process.

6)+7) Sputtering of TiW and Au Sandwich 33 (+Electroplating of Au if Needed):

The TiW diffusion/adhesion layer and Au protection/seed layers are deposited by means of sputtering and together form a metal sandwich 33. If needed, an Au layer will be electroplated in order to provide a dense surface film.

8) Deposition of Mechanical Protective Photoresist Layer 34:

A thick layer of photoresist 34 is deposited on the front side of the wafer in order to provide mechanical protection when placing the wafer on the waferholder in the subsequent RIE step. Alternatively the mechanical protective layer 34 can be a metal layer which can be sacrificially etched later in the processing. The choice of protective layer is made according to the clean-room equipment available.

9)+10) Patterning of PECVD Nitride on Back Side:

In order to define the openings 35 in the protective nitride layer a standard photolithographic process is performed, i.e. a photosensitive material (a photoresist) is spun, exposed and developed. The exposure through a photo-mask has to be performed in a double-sided aligner, since the nitride pattern has to be aligned to features (the circuits) at the front side of the wafer. Subsequent to the development of the resist, the nitride not covered by cured photoresist can be etched selectively using a SF₆/O₂ based RIB process.

11) Stripping of Photoresist:

The mechanical protective photoresist layer 34 on the front side and the photoresist on the back side of the wafer are stripped simultaneously.

12) Etching of Through-Holes 36:

The through-holes 36 are anisotropically etched using a KOH solution at a suitable temperature yielding a typical etch rate in the region of 80 μm per hour. A process time around 7 hours for a wafer thickness of 600 μm may be obtained. The potassium ions are a potential threat to the sensitive CMOS circuit, and it is therefore very important to avoid any contact with the front side of the wafer (the front side is therefore protected by a TiW/Au metal sandwich 33 as well as a silicon nitride layer 30).

The etching process is self-terminating as it stops at the silicon nitride barrier 30 on the front side of the wafer. Thus, the KOH etching process leaves a thin silicon nitride membrane, which subsequently has to be removed.

13) Deposition of Protective Layer 37 on Front Side:

Prior to removal of the formed membrane a mechanical protective photoresist layer 37 is deposited on the front of the wafer. Alternatively the mechanical protective layer 37 can be a metal layer as mentioned above. In this case the metallic protection layer has to be resistant to the Au etching process and it has to be able to be sacrificially etched later in the processing.

14) Etch of Silicon Nitride Membrane 30 from Back Side:

The through-holes are opened from the back side by wet or dry etching of the exposed parts of the front silicon nitride 30 (inside the through-holes).

Preferably the exposed part of the front side silicon nitride 30 is etched in a RIE process wherein the etch rate of silicon is larger than the etch rate of silicon nitride. In such a RIE process the sloped silicon walls of the through-hole will be etched faster than the silicon nitride membrane, thereby yielding a structure having a small part of the silicon nitride 38 on the front side overhanging from the through-hole opening defined by the silicon. This process also removes the etch resistant silicon nitride 31 on the back side.

Alternatively a wet etch step may be employed to etch the silicon nitride 30 and open the through-holes. This process also removes the etch resistant silicon nitride 31 on the back side.

In case a wet etching process has been used for removal of the exposed part of the front silicon nitride 30 (inside the through-holes) a silicon etch-back process step is necessary. The wet etch is isotropic in nature, which means that the nitride layer is also attacked in the lateral direction. Thus, a small under-etch is formed during formation of the openings, resulting in a highly convex silicon edge. This edge is very difficult to coat uniformly, which means that it is difficult to obtain proper insulation of the feedthrough. In order to alter the structure of the edge into a structure that enables proper uniform coating, a silicon etch-back step is performed. A few microns of the silicon sidewalls are etched using e.g. a HF:HNO₃ solution in order to remove the under-etch. After the silicon etch-back a small nitride nose is formed, which is perfectly suited for uniform coating and hence good insulation of the feedthrough.

15) Wet Etching of TiW and Au Sandwich 33:

The exposed parts of the front side TiW/Au coating 33 are etched from the back side using wet chemistry. Typically TiW can be etched using H₂O₂ and Au can be etched using a commercially available etchant capable of etching Au selectively to TiW and selectively to a range of other metals. A minor underetch problem may occur here, since etching of metals is isotropic in nature.

Alternatively the front side KOH resistant metallic layer(s) are removed in a mask less etching process and a local part of the front side electrical insulation layer is subsequently removed using a photolithographic process on the front side in alignment with the formed through-holes followed by an etching process.

16) Stripping of Front Protection:

The protective photoresist coating 37 on the front of the wafer is no longer needed and is therefore stripped. In case a metallic protection layer has been used this layer is selectively removed in this process step.

17) Deposition of PECVD Oxide 39 on Back Side:

The needed dielectric layer 39 on the back side is deposited by means of PECVD. The step coverage of this process is quite critical for the final performance of the feed-through. If the underetch mentioned in item 15) is too pronounced, it may be difficult for the PECVD oxide 39 to cover the nitride/TiW/Au interface properly, i.e. it may be difficult to obtain an efficient isolation.

Even though the front of the wafer is turned away from the plasma in the PECVD chamber a thin oxide layer 40 deposits on it, especially in proximity of the through-hole openings.

18) Cleaning of Front Side Wafer Surface:

In order to ensure proper electrical contact the formed oxide 40 on the front of the wafer has to be removed. The thin oxide 40 on the front of the wafer is removed using sputter etching.

Alternatively the thin oxide 40 on the front of the wafer is removed by immersing the wafer into a buffered oxide etchant (containing HF) for a short period of time. This process will also affect the silicon oxide on the back side of the wafer, but due to the larger thickness of silicon oxide on the back side this has no practical consequences.

19) Evaporation of Ti/Au on Back Side:

In order to provide the electrical connection from front to back of the wafer a plating base 40 is deposited on the back side. The plating base 41 consists of a Ti adhesion layer and an Au seed layer. Both layers are deposited by means of evaporation.

20) Electrochemical Deposition of Photoresist 42:

In order to define the structure of the feedthrough a plating mould is needed. The plating mould constitutes the negative image of the actual feed-through, and by deposition of metal into the mould the actual feed-through will be formed. For ordinary applications the plating mould is formed in a standard photoresist, but for the special purpose of wafer through-holes a dedicated photoresist has to be used since standard resist coating techniques like spin coating are not able to uniformly fill the through-holes. An electrodepositable photoresist 42 is deposited from a bath containing the resist constituents in a process similar to ordinary electrolytic processes. The wafer is electrically contacted to a power supply and subsequently immersed into the bath together with a counterelectrode (as cathode and anode, respectively). By applying a voltage between the two electrodes photoresist 42 is deposited at the wafer surface in a uniform and conformal layer. The process is self-terminating, and the deposited resist thickness depends on the specific composition of the plating bath, the temperature and the applied voltage.

Another option is to have the semiconductor wafer including the etched through-holes covered by photoresist by a spray coating process as this process is also capable of applying a uniform coat to highly structured surfaces.

21) Photolithography of EP Photoresist:

The photoresist on front and back side of the wafer is exposed sequentially through a mask defining the negative image of the feed-through. Subsequently the photoresist is developed.

22) Electrochemical Deposition of Cu:

The feed-throughs 43 are formed by electrochemical deposition of Cu or a combination of electrochemical deposition of Cu and Ni.

23)+24) Stripping of Photoresist and Selective Etch of Plating Base:

The photoresist and the underlying TiW/Au plating base is selectively removed to the Cu.

25)+26) Passivation of Semiconductor Wafer with Electrical Feedthroughs:

The semiconductor wafer with fully processed electrical feedthroughs needs to be passivated in order to protect it from the ambient environment Preferably the semiconductor wafer is passivated by BCB (BenzoCycloButene) 44 or by a combination of BCB and a PECVD processed layer such as silicon oxide, silicon nitride or silicon oxynitride.

The BCB passivation 44 is patterned by UV-illumination through a photomask as in a standard photoresist process. The BCB passivation 44 is removed in metallized areas designed for terminals for input/output signals and in metallized areas designed for later processing of solder bumps. In case a PECVD processed passivation layer is applied beneath the BCB passivation, this layer is subsequently removed in a reactive ion etching process using the developed BCB layer as an etch mask.

1. Process for generating a feed-through in a semiconductor wafer which has electric circuitry embedded in a front surface whereby a hole for the feed-through is generated by the combined use of a front side protection layer and a wet KOH etch process etching the hole from a back side of the wafer, where a photomaking process is subsequently used do define the vias followed by deposition of via material.

2. Process as claimed in claim 1, where the front side protection layer comprises: a) an electrical insulation layer, preferably a PECVD silicon nitride layer; b) a KOH resistant metallic layer, preferably a TiW layer and an Au layer.

3. Process as claimed in claim 1, whereby the etch process from the back side takes place in a number of steps:
a KOH etch resistant layer is deposited on the back side,
openings for the through-holes are defined in the KOH etch resistant layer using a photomasking process in alignment with the circuitry embedded in the front side silicon,
the openings for the through-holes are etched in the KOH resistant layer, and
the through-holes are in the silicon are etched in a KOH bath.

4. Process as claimed in claim 3, whereby the front side electric insulation and the KOH etch-resistant metallic layers covering the through-holes are etched from the back side through the formed holes in the silicon.

5. Process as claimed in claim 3, whereby the front side electric insulation and the KOH etch-resistant metallic layers covering the through-holes are etched from the front side, preferably using a photomasking process in alignment with the through-holes.

6. Process as claimed in claim 5, whereby the inside of the etched holes and back side of the wafer are covered with an insulation layer, preferably a PECVD deposited insulation layer, and the insulation layer is covered with a plating base, preferably by deposition of a TiW adhesion layer and an Au layer.

7. Process as defined in claim 6, where residual insulation material on the front side originating from the PECVD process on the back side, especially in the areas around the holes is removed, preferably by sputter etching.

8. Process as defined in claim 1, whereby the photomasking process comprises deposition of an electrodeposited photoresist, whereby the deposited photoresist is exposed through a mask defining the negative image of the feed-through back and front side respectively and where the photoresist is developed and the feed-through is subsequently formed by deposition of metal.

9. Process as claimed in claim 8, whereby the feed-through is formed by deposition of Cu and Ni.

10. Amplifier produced according to claim 1, wherein terminals for gaining contact with the CMOS structure embedded in the surface of a front side of semiconductor wafer are placed on both back and front sides of the wafer and where a feed-through connects the terminals on the back side with the CMOS circuitry embedded in the front side of the wafer.
